(19) United States
(12) Patent Application Publication
(10) Pub. No.: US 2012/0073641 A1
(43) Pub. Date: Mar. 29, 2012

(54) Solar cell apparatus having the transparent conducting layer with the structure as a plurality of nano-level well-arranged arrays

(75) Inventors: Ping-Chen Tseng, Kaohsiung City (TW); Peichen Yu, Hsinchu City (TW); Hao-Chung Kuo, Hsinchu City (TW)

(73) Assignee: National Chiao Tung University, Hsinchu City (TW)

(21) Appl. No.: 12/929,218

(22) Filed: Jan. 10, 2011

(30) Foreign Application Priority Data
Sep. 24, 2010 (TW) 099132277

(51) Int. Cl. H01L 31/0232

(52) U.S. Cl. 136/256

(57) ABSTRACT

The invention discloses an apparatus for enhancing light absorption of solar cells and photodetectors by diffraction. The invention comprises the structure as the plurality of nano-level well-arranged arrays with a plurality of certain defect areas including the shapes of rod, tapered-cone, and cone, which diffracts incident light to oblique angles for light trapping. Surface reflection can also be reduced for either broadband or narrow band spectral absorption. The increased contact area between the transparent conducting layer and photoactive layer is beneficial for current extraction, which increases the internal quantum efficiency (IQE).

### BACKGROUND OF THE INVENTION

1. Field of the Invention

The invention relates to a solar cell apparatus, particularly to a solar cell apparatus having the transparent conducting layer with the structure as a plurality of nano-level well-arranged arrays.

2. Description of the Prior Art

After the financial tsunami of 2008, a lot of global countries realize that it is necessary to develop the green energy industry, in order to become the important response of future national development and the promoting goal of industry. Therefore, the green energy industry has already become the global main motive source of economic development, and even become the prior industry developed by every advanced country at present. Taiwan also promotes the green energy industry in a more cost-effective manner at present, particularly regards the solar energy industry as the main green energy industry for the development in the future.

The polysilicon solar cell is the main product of solar energy industry at present. However, the polysilicon material is very expensive, it is difficulty to make large-area product, thus it is unfavorable to be used in industry. In addition, its current conversion efficiency is very low, thus present academic research and industry turn to more research and development and use of thin film solar cell. The main consideration is to make the material with the larger area and bigger efficiency quickly. However, due to the thin film solar cell is too thin, the optical absorption path become too short, the efficiency of thin film solar cell produced by present technique is generally not high. Thus, there is a great improvement space for the research and development.

In the U.S. Pat. No. 6,750,393, the three-dimensional photonic crystal is made at the back of solar cell, in order to obtain the effect of light trapping. However, its design and manufacturing is very difficult. When the photonic crystal is placed inside the solar cell, the photonic current is apt to be trapped inside, thus as to reduce the cell efficiency instead.

The U.S. Pat. No. 7,482,532 providing the textured distributed Bragg reflector (DBR) is made at the back of solar cell, in order to obtain the effect of light trapping and high reflection rate. Its purpose is to substitute the metal reflection layer. However, this DBR structure is unable to provide the anti-reflection effect actually. Moreover, this DBR structure includes an insulation layer, thus it is apt to increase the resistance value instead.

In the prior art of the U.S. Pat. No. 6,858,462, the etching periodic structure of silicon substrate surface is used. Although the light trapping effect can be achieved, the surface defect is apt to be produced because of etching process. The electron and electric hole are extremely easy to be trapped onto the surface, so that the current is unable to be extracted effectively, and the cell efficiency will be reduced.

Therefore, in order to produce better solar cell, and offer better solar cell production technology to the industry, it is necessary to develop innovative solar cell production process technology, so as to improve the cell efficiency of solar cell, and reduce the manufacturing cost of solar cell.

### SUMMARY OF THE INVENTION

The invention relates to a solar cell apparatus having the transparent conducting layer with the structure as a plurality of nano-level well-arranged arrays with a plurality of certain defect areas, wherein the plurality of nano-level well-arranged arrays is a periodic or a quasi-periodic. The invention comprises a transparent substrate. A transparent conducting electrode is formed on the transparent substrate, and a photoactive layer is formed on the transparent conducting electrode. The transparent conducting electrode has the structure as a plurality of nano-level well-arranged arrays with a plurality of certain defect areas, wherein the plurality of nano-level well-arranged arrays is a periodic or a quasi-periodic, including the types of rod-shaped, trapezium-shaped, cone-shaped, tapered-cone-shaped, and nipple-shaped and so on.

The invention can solve the problem that due to the thickness of thin film solar cell and photodetector is too thin, thus the effective absorption length is unable to be provided.

The invention uses the structure as a plurality of nano-level well-arranged arrays, wherein the plurality of nano-level well-arranged arrays is a periodic or a quasi-periodic with a plurality of certain defect areas, to trap the light in the limited thickness of thin film solar cell, and increase the contact area of photoactive layer and electrode.

The nano-structure of the invention can provide the anti-reflection effect, and increase the photons entering into the photoactive layer.

The invention uses the transparent conducting electrode to form the nano-structure, thus the electron-hole pair generated from the photoactive layer is easier to be collected by the electrode, and finally can increase the internal quantum efficiency.

The invention can increase the contact area of solar cell material and transparent conducting electrode, and the electrical current can be extracted more efficiently due to the increase for the contact area of electrode and photoactive layer.

The invention can be used in the photonic crystal of large-area process, and use the light trapping feature and anti-reflection effect of photonic crystal to various thin film solar cells and photodetectors, in order to increase the photon absorption rate and reach higher photovoltaic conversion efficiency.

Therefore, the advantage and spirit of the invention can be understood further by the following detail description of invention and attached figures.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1A is a graph illustrating the first embodiment of the invention.

FIG. 1B is a graph illustrating the structure of transparent conducting electrode for the first embodiment of the invention.

FIG. 2A is a graph illustrating the second embodiment of the invention.

FIG. 2B is a graph illustrating the structure of transparent conducting electrode for the second embodiment of the invention.

FIG. 3A is a graph illustrating the third embodiment of the invention.

FIG. 3B is a graph illustrating the structure of transparent conducting electrode for the third embodiment of the invention.

FIG. 4A is a graph illustrating the fourth embodiment of the invention.

FIG. 4B is a graph illustrating the structure of transparent conducting electrode for the fourth embodiment of the invention.

FIG. 5A is a graph illustrating the fifth embodiment of the invention.

FIG. 5B is a graph illustrating the structure of transparent conducting electrode for the fifth embodiment of the invention.

### DESCRIPTION OF THE PREFERRED EMBODIMENT

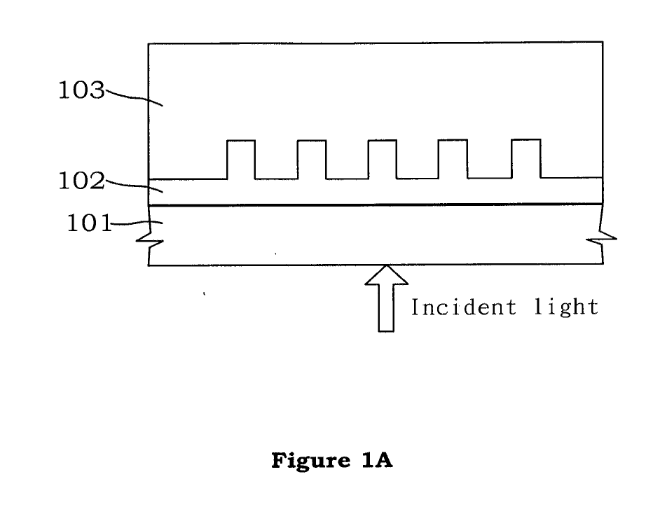

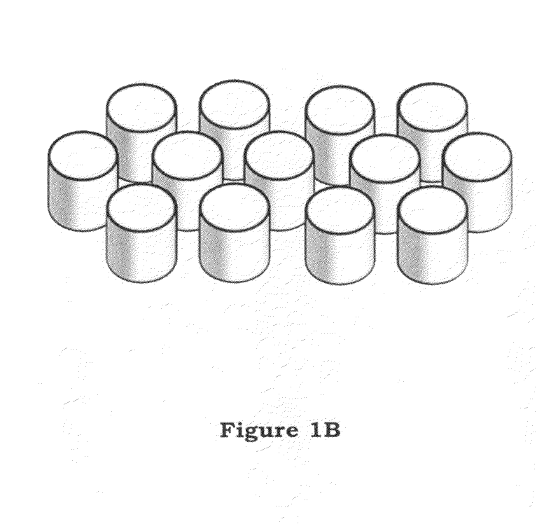

The invention relates to a solar cell apparatus having the transparent conducting layer with the structure as a plurality of nano-level well-arranged arrays with a plurality of certain defect areas, wherein the plurality of nano-level well-arranged arrays is a periodic or a quasi-periodic. The first embodiment is shown in FIG. 1A. A transparent substrate 101 is provided at first. The glass or sapphire is selected as the transparent substrate 101.

As shown in FIG. 1A, the chemical vapor deposition (CVD) is used to form a transparent conducting electrode (TCO) 102 on the transparent substrate 101. The material of transparent conducting electrode 102 includes the indium tin oxide (ITO) and aluminum zinc oxide (AZO), which has the conduction and light penetration property. The polystyrene spheres colloidal lithography and physical or chemical etching method are used to form the rod-shaped photonic crystal or quasi-photonic crystal on the transparent conducting electrode 102.

As shown in FIG. 1A again, the chemical vapor deposition (CVD) is used to form a photoactive layer 103 on the transparent conducting electrode 102. The photoactive layer 103 is mainly a material which can form the electron and electric hole, including solar cell material. The crystalline silicon and amorphous silicon can be formed on the transparent conducting electrode 102 by the chemical vapor deposition.

FIG. 1B is a graph illustrating the rod-shaped photonic crystal or quasi-photonic crystal on the transparent conducting electrode 102, which has symmetrical arrangement and asymmetrical arrangement, thus it has the shape of cyclic arrangement.

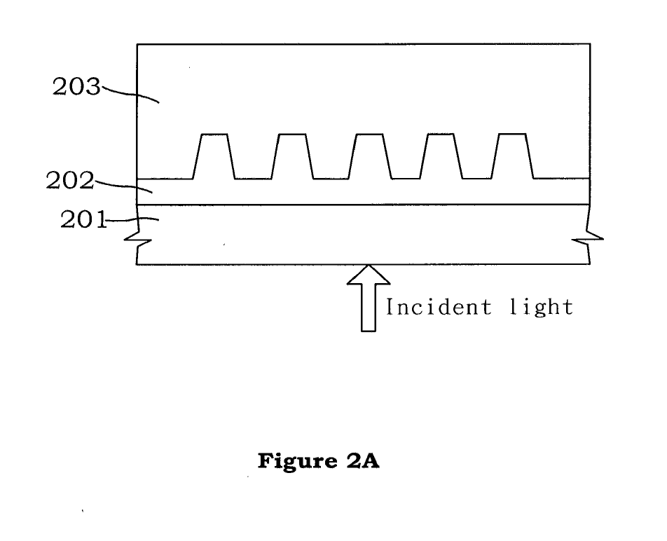

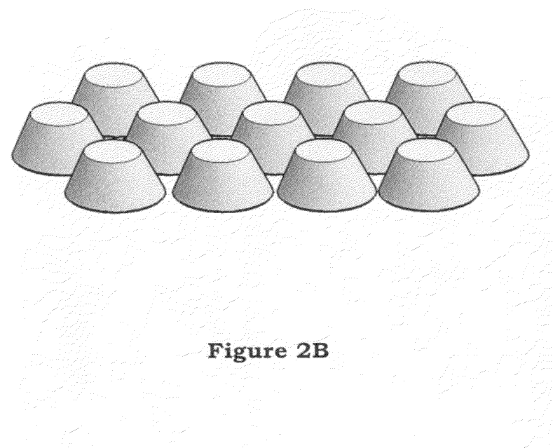

The second embodiment of the invention is shown in FIG. 2A. A transparent substrate 201 is provided at first. The glass or sapphire is selected as the transparent substrate 201.

As shown in FIG. 2A, the chemical vapor deposition is used to form a transparent conducting electrode 202 on the transparent substrate 201. The material of transparent conducting electrode 202 includes the indium tin oxide (ITO) and aluminum zinc oxide (AZO), which has the conduction and light penetration property. The polystyrene spheres colloidal lithography and physical or chemical etching method are used to form the trapezium-shaped photonic crystal or quasi-photonic crystal on the transparent conducting electrode 202.

As shown in FIG. 2A again, the chemical vapor deposition is used to form a photoactive layer 203 on the transparent conducting electrode 202. The photoactive layer 203 is mainly a material which can form the electron and electric hole, including solar cell material. The crystalline silicon and amorphous silicon can be formed on the transparent conducting electrode 202 by the chemical vapor deposition.

FIG. 2B is a graph illustrating the trapezium-shaped photonic crystal or quasi-photonic crystal on the transparent conducting electrode 202, which has symmetrical arrangement and asymmetrical arrangement, thus it has the shape of cyclic arrangement.

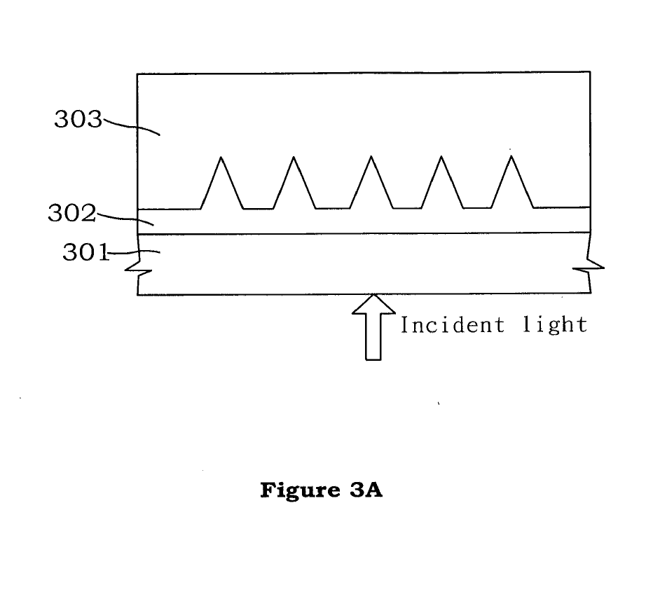

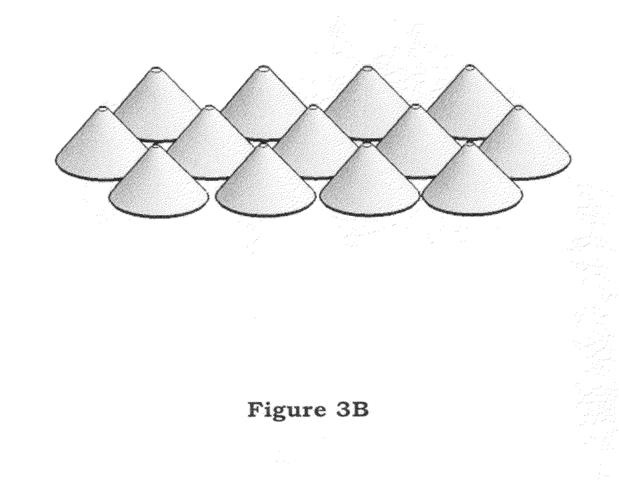

The third embodiment of the invention is shown in FIG. 3A. A transparent substrate 301 is provided at first. The glass or sapphire is selected as the transparent substrate 301.

As shown in FIG. 3A, the chemical vapor deposition is used to form a transparent conducting electrode 303 on the transparent substrate 301. The material of transparent conducting electrode 303 includes the indium tin oxide (ITO) and aluminum zinc oxide (AZO), which has the conduction and light penetration property. The polystyrene spheres colloidal lithography and physical or chemical etching method are used to form the cone-shaped photonic crystal or quasi-photonic crystal on the transparent conducting electrode 303.

As shown in FIG. 3A again, the chemical vapor deposition is used to form a photoactive layer 303 on the transparent conducting electrode 303. The photoactive layer 303 is mainly a material which can form the electron and electric hole, including solar cell material. The crystalline silicon and amorphous silicon can be formed on the transparent conducting electrode 303 by the chemical vapor deposition.

FIG. 3B is a graph illustrating the cone-shaped photonic crystal or quasi-photonic crystal on the transparent conducting electrode 303, which has symmetrical arrangement and asymmetrical arrangement, thus it has the shape of cyclic arrangement.

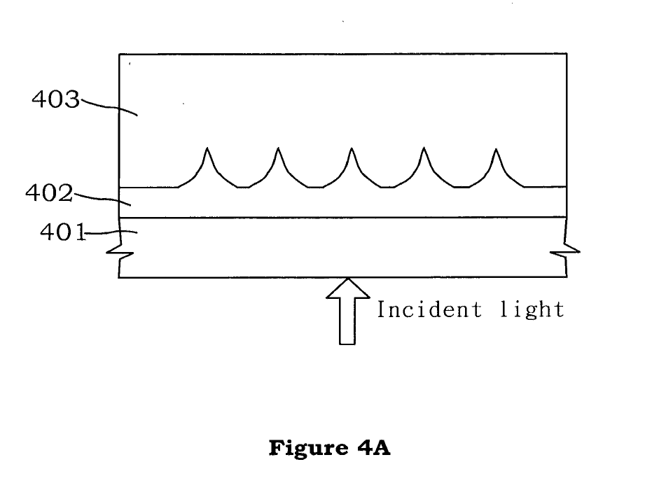

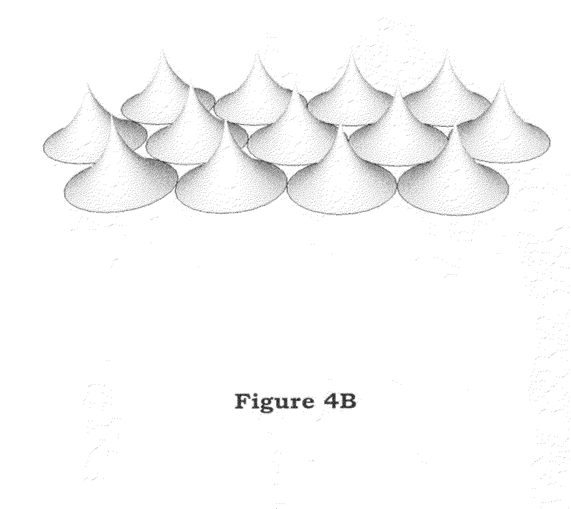

The fourth embodiment of the invention is shown in FIG. 4A. A transparent substrate 401 is provided at first. The glass or sapphire is selected as the transparent substrate 401.

As shown in FIG. 4A, the chemical vapor deposition is used to form a transparent conducting electrode 404 on the transparent substrate 401. The material of transparent conducting electrode 404 includes the indium tin oxide (ITO) and aluminum zinc oxide (AZO), which has the conduction and light penetration property. The polystyrene spheres colloidal lithography and physical or chemical etching method are used to form the tapered-shaped photonic crystal or quasi-photonic crystal on the transparent conducting electrode 404.

As shown in FIG. 4A again, the chemical vapor deposition is used to form a photoactive layer 403 on the transparent conducting electrode 404. The photoactive layer 403 is mainly a material which can form the electron and electric hole, including solar cell material. The crystalline silicon and amorphous silicon can be formed on the transparent conducting electrode 404 by the chemical vapor deposition.

FIG. 4B is a graph illustrating the tapered-shaped photonic crystal or quasi-photonic crystal on the transparent conducting electrode 404, which has symmetrical arrangement and asymmetrical arrangement, thus it has the shape of cyclic arrangement.

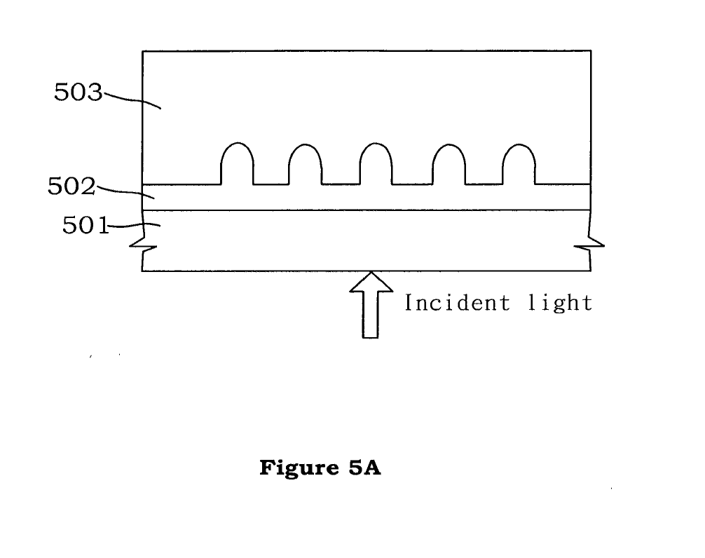

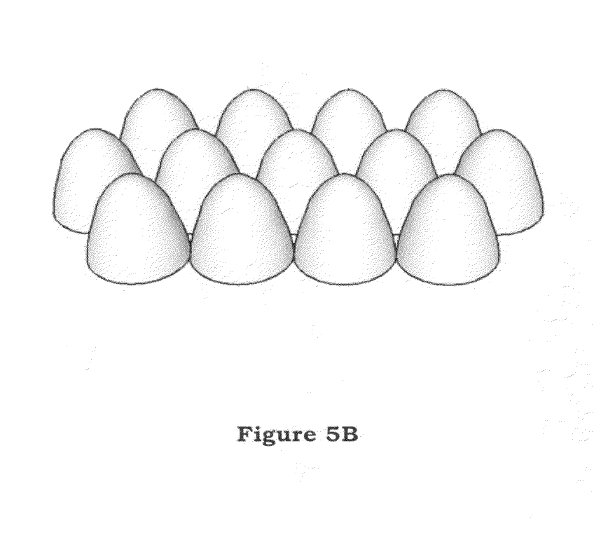

The fifth embodiment of the invention is shown in FIG. 5A. A transparent substrate 501 is provided at first. The glass or sapphire is selected as the transparent substrate 501.

As shown in FIG. 5A, the chemical vapor deposition is used to form a transparent conducting electrode 505 on the transparent substrate 501. The material of transparent conducting electrode 505 includes the indium tin oxide (ITO) and aluminum zinc oxide (AZO), which has the conduction and light penetration property. The polystyrene spheres colloidal lithography and physical or chemical etching method are used to form the nipple-shaped photonic crystal or quasi-photonic crystal on the transparent conducting electrode 505.

As shown in FIG. 5A again, the chemical vapor deposition is used to form a photoactive layer 503 on the transparent conducting electrode 505. The photoactive layer 503 is mainly a material which can form the electron and electric hole, including solar cell material. The crystalline silicon and amorphous silicon can be formed on the transparent conducting electrode 505 by the chemical vapor deposition.

FIG. 5B is a graph illustrating the nipple-shaped photonic crystal or quasi-photonic crystal on the transparent conducting electrode 505, which has symmetrical arrangement and asymmetrical arrangement, thus it has the shape of cyclic arrangement.

The invention makes the photonic crystal or quasi-photonic crystal with cyclic structure on the transparent conducting electrode of solar cell, in order to produce the light diffraction and the light scattering. The incident light can diffract and scatter in the solar cell, increase the light path and increase its absorption, and obtain the light trapping effect in the photoactive layer. This structure has the anti-reflection effect on the surface, which causes the increase of incident light. The invention uses the transparent conducting electrode to form the structure as the plurality of nano-level well-arranged arrays with a plurality of certain defect areas, wherein the plurality of nano-level well-arranged arrays is a periodic or a quasi-periodic, thus the electron-hole pair generated from the photoactive layer is easier to be collected by the electrode. The invention can increase the contact area of electrode and photoactive layer, and the electrical current can be extracted more efficiently and the internal quantum efficiency can be increased effectively. Summarized from the above-mentioned description, the invention can be applied to and designed in various solar cell materials and photodetectors, in order to increase the absorption efficiency of solar light.

The invention uses the nano-level well-arranged arrays to trap the light in the limited thickness of thin film solar cell, and increase the contact area of photoactive layer and electrode. The invention can solve the problem that due to the thickness of thin film solar cell and photodetector is too thin, thus the effective absorption length is unable to be provided.

It is understood that various other modifications will be apparent to and can be readily made by those skilled in the art without departing from the scope and spirit of this invention. Accordingly, it is not intended that the scope of the claims appended hereto be limited to the description as set forth herein, but rather that the claims be construed as encompassing all the features of patentable novelty that reside in the present invention, including all features that would be treated as equivalents thereof by those skilled in the art to which this invention pertains.

What is claimed is:

1. A solar cell apparatus, comprising:
a transparent conducting electrode being formed on a transparent substrate and a photoactive layer.

2. The apparatus according to claim 1, wherein the transparent conducting electrode comprises a structure as a plurality of nano-level well-arranged arrays with a plurality of certain defect areas.

3. The apparatus according to claim 2, wherein the plurality of nano-level well-arranged arrays is selected from the group consisting of periodic and quasi-periodic.

4. The apparatus according to claim 1, wherein the transparent conducting electrode is selected from the group consisting of indium tin oxide (ITO) and aluminum zinc oxide (AZO).

5. The apparatus according to claim 1, the transparent substrate is selected from the group consisting of a plurality of types of rod-shaped, trapezium-shaped, cone-shaped, tapered-cone-shaped, and nipple-shaped.

6. The apparatus according to claim 1, wherein the photoactive layer is selected from the group consisting of crystalline silicon and amorphous silicon.

7. A solar cell apparatus having the transparent conducting layer with a structure as a plurality of nano-level well-arranged arrays with a plurality of certain defect areas, comprising:
a transparent substrate;
a transparent conducting electrode with a structure as a plurality of nano-level well-arranged arrays with a plurality of certain defect areas, being formed on the transparent substrate; and
a photoactive layer being formed on the transparent conducting electrode.

8. The apparatus according to claim 7, wherein the transparent substrate is selected from the group consisting of glass and sapphire.

9. The apparatus according to claim 8, the glass or sapphire is selected from the group consisting of a plurality of types of rod-shaped, trapezium-shaped, cone-shaped, tapered-cone-shaped, and nipple-shaped.

10. The apparatus according to claim 7, wherein the plurality of nano-level well-arranged arrays with a plurality of certain defect areas is selected from the group consisting of periodic and quasi-periodic.

11. The apparatus according to claim 7, wherein the transparent conducting electrode is selected from the group consisting of indium tin oxide (ITO) and aluminum zinc oxide (AZO).

12. The apparatus according to claim 7, wherein the transparent conducting electrode is formed by a chemical vapor deposition method, a polystyrene spheres colloidal lithography method, and an etching method.

13. The apparatus according to claim 7, wherein the transparent conducting electrode comprises a photonic crystal.

14. The apparatus according to claim 13, wherein the photonic crystal further comprises a quasi-photonic crystal.

15. The apparatus according to claim 14, wherein the quasi-photonic crystal has a symmetrical arrangement and an asymmetrical arrangement, and has a shape of cyclic arrangement.

16. The apparatus according to claim 13, wherein the photonic crystal has symmetrical and asymmetrical arrangement, and has the shape of cyclic arrangement.

17. The apparatus according to claim 7, wherein the photoactive layer is selected from the group consisting of crystalline silicon and amorphous silicon.
